(19) United States
(12) Patent Application Publication
(10) Pub. No.: US 2025/0362334 A1
(43) Pub. Date: Nov. 27, 2025

(54) Semiconductor Fault Detection

(71) Applicant: Google LLC, Mountain View, CA (US)

(72) Inventors: Lesly Zaren Venturina Endrinal, San Diego, CA (US); Achin Grover, Bangalore (IN); Rakesh Kumar Kinger, Newark, CA (US)

(73) Assignee: Google LLC, Mountain View, CA (US)

(21) Appl. No.: 18/886,620

(22) Filed: Sep. 16, 2024

Related U.S. Application Data
(60) Provisional application No. 63/650,673, filed on May 22, 2024.

(51) Int. Cl. G01R 31/26; H01L 23/485; H01L 23/528

(52) U.S. Cl. CPC G01R 31/2644; H01L 23/485; H01L 23/528

(57) ABSTRACT

This document describes systems and techniques directed at semiconductor fault detection. In aspects, a semiconductor device includes a physical structure that facilitates detection and localization of defects. The physical structure includes at least one conductive interconnect that extends through two or more layers of a semiconductor device, enabling an electrical detection of faults. Such systems and techniques can help improve yield, accelerate failure analysis debugging, and improve reliability of semiconductor devices.

### CROSS-REFERENCE TO RELATED APPLICATION(S)

This application claims the benefit of U.S. Provisional Patent Application Ser. No. 63/650,673, filed on May 22, 2024, the disclosure of which is incorporated by reference herein in its entirety.

### BACKGROUND

Semiconductor devices have markedly enhanced electronics. Modern electronics perform more-complex computations with greater speed and efficiency than its predecessors from decades prior. Their unique properties allow precise control over electric currents, resulting in smaller, faster, and more energy-efficient devices. One of the key benefits of semiconductor devices is their scalability. Millions to billions of transistors can be electrically integrated within a package sized around 100 square millimeters on a single semiconductor device. This scalability has driven the miniaturization of electronic devices, including wearables and micro-electromechanical systems.

Advancements in semiconductor technology have also led to improved performance and energy efficiency. Manufacturers constantly push the limits of semiconductor materials and fabrication techniques to produce faster processors, higher-resolution displays, and longer-lasting batteries. However, semiconductor dies are prone to faults, including physical and/or electrical defects, that may arise during manufacturing and/or handling. These defects (e.g., die cracks) can significantly reduce the reliability, performance, and lifespan of a semiconductor device and the larger electronic device. Physical defects can undermine electrical connections, mechanical integrity (e.g., delamination), thermal management, and ingress containment prevention, leading to corrosion and oxidation.

The edge of a semiconductor die is particularly susceptible to failure due to high package-to-Silicon interaction stress, direct exposure to an environment, and manufacturing flaws. Current failure analysis techniques for fault detection, such as x-ray imaging and scanning acoustic microscopy, attempt to detect faults, such as micro-cracks, before semiconductor devices are integrated into electronic products. However, as semiconductor devices grow in complexity and shrink in size, detecting defects is becoming increasingly important and challenging. Using current failure analysis techniques, many defects (e.g., nano-scale defects, micro-cracks) go undetected.

In addition, semiconductor devices are regularly exposed to reliability tests, including thermal cycling and thermal shock, to determine and ensure a dependability of these devices. However, current failure analysis techniques often provide inadequate test results due to a lack of resolution in the data, leading to imprecise quality assurance estimates and lifetime expectancies.

This Background section is provided to generally present the context of the disclosure. Unless otherwise indicated herein, material described in this section is neither expressly nor implicitly admitted to be prior art to the present disclosure or the appended claims.

### SUMMARY

This document describes systems and techniques directed at semiconductor fault detection. In aspects, a semiconductor device includes a physical structure that facilitates detection and localization of defects. The physical structure includes at least one conductive interconnect that extends through two or more layers of a semiconductor device, enabling an electrical detection of faults. Such systems and techniques can help improve yield, accelerate failure analysis debugging, and improve reliability of semiconductor devices.

In aspects, a semiconductor device is disclosed that includes: two or more stacked layers. The two or more stacked layers include a first semiconductor layer and a second semiconductor layer. The first semiconductor layer having a topmost surface, a bottommost surface opposite the topmost surface, a first electrical terminal electrically accessible at the topmost surface, and a second electrical terminal electrically accessible at the topmost surface. The first semiconductor layer further having a first conductive interconnect portion configured to be in electrical communication with the first electrical terminal and extending, from the first electrical terminal and through the first semiconductor layer, to the bottommost surface. The first semiconductor layer also having a second conductive interconnect portion configured to be in electrical communication with the second electrical terminal and extending, from the second electrical terminal and through the first semiconductor layer, to the bottommost surface. The second semiconductor layer includes a second topmost surface, a second bottommost surface opposite the second topmost surface of the second semiconductor layer and opposite the topmost surface of the first semiconductor layer, and a third conductive interconnect portion configured to be in electrical communication with the first conductive interconnect portion and electrically extending from the first conductive interconnect portion and into at least a portion of the second semiconductor layer. The second semiconductor layer further having a fourth conductive interconnect portion configured to be in electrical communication with the second conductive interconnect portion and electrically extending from the second conductive interconnect portion and into at least a second portion of the second semiconductor layer. The second semiconductor layer also having an interfacing region having a fifth conductive interconnect portion configured to be in electrical communication with the third conductive interconnect portion and the fourth conductive interconnect portion. The first conductive interconnect portion, the second conductive interconnect portion, the third conductive interconnect portion, the fourth conductive interconnect portion, the interfacing region, and the fifth conductive interconnect portion defining a first conductive interconnect usable to localize a fault in the semiconductor device.

The details of one or more implementations are set forth in the accompanying Drawings and the following Detailed Description. Other features and advantages will be apparent from the Detailed Description, the Drawings, and the Claims. This Summary is provided to introduce subject matter that is further described in the Detailed Description. Accordingly, a reader should not consider the Summary to describe essential features or limit the scope of the claimed subject matter.

### BRIEF DESCRIPTION OF THE DRAWINGS

Systems and techniques directed at semiconductor fault detection are described with reference to the following drawings. The same numbers are used throughout the drawings to reference like features and components:

FIG. 1 illustrates an example electronic device with a semiconductor device configured for fault detection.

FIG. 2 illustrates an example semiconductor device that includes a plurality of standard cells and additional hardware elements.

FIG. 3 illustrates an example partial, cross-sectional diagram of stacked layers of an example semiconductor device in accordance with one or more implementations.

FIG. 4 illustrates another example partial, cross-sectional diagram of stacked layers of an example semiconductor device in accordance with one or more implementations.

FIG. 5 illustrates a still further example partial, cross-sectional diagram of stacked layers of an example semiconductor device in accordance with one or more implementations.

FIG. 6 illustrates an example implementation of an example standard cell in accordance with one or more implementations.

FIG. 7 illustrates an example implementation of an example standard cell in accordance with one or more implementations.

FIG. 8 illustrates an example test procedure table for a standard cell of a semiconductor device to detect faults.

FIG. 9 illustrates various components of an example electronic device that can include a semiconductor configured for fault detection in accordance with one or more described aspects.

### DETAILED DESCRIPTION

### Overview

Electronic devices, such as smartphones and laptops, utilize a plurality of electrical components, including semiconductor devices. Semiconductor devices may be implemented as, for example only and not by way of limitation, discrete devices (e.g., diodes, transistors), optical devices (e.g., light-emitting diodes), microwave devices, sensors, processors, integrated circuits, and other such devices. These semiconductor devices control the flow of electrical current, enabling them to gain up or down electronic signals, switch electronic signals on and off, process electronic signals, perform energy conversion, store data, and/or execute additional services in electronic circuits. In one example, a semiconductor device (e.g., a chip) may be implemented as an integrated circuit having multiple functional elements mounted on a semiconductor die. As described herein, a semiconductor die is a block of semiconductor material (e.g., silicon) on which a functional circuit can be fabricated. In aspects, for purposes of the following disclosure, a semiconductor device may include the semiconductor die and, optionally, one or more electrical components (e.g., an integrated circuit) fabricated thereon.

During manufacturing and fabrication, a semiconductor device (e.g., the semiconductor die) may develop faults, such as physical and/or electrical defects. These faults may manifest as micro-scale or nano-scale cracks and/or chips in the semiconductor device. For example, these faults may develop during laser processing, wafer sawing, or the like. A fault may disrupt an electrical connection between one or more layers or regions of the semiconductor device, resulting in sub-optimal performance and reliability. Current failure analysis techniques for fault detection, such as x-ray imaging and scanning acoustic microscopy, attempt to detect faults, such as micro-cracks, before semiconductor devices are integrated into electronic products. However, as semiconductor devices grow in complexity and shrink in size, detecting defects is becoming increasingly important and challenging. Using current failure analysis techniques, many defects (e.g., nano-scale defects, micro-cracks) go undetected.

To this end, this document describes systems and techniques directed at semiconductor fault detection. In aspects, a semiconductor device includes a physical structure that facilitates detection and localization of defects. The physical structure includes at least one conductive interconnect that extends through two or more layers of a semiconductor device, enabling an electrical detection of faults. Such systems and techniques can help improve yield, accelerate failure analysis debugging, and improve reliability of semiconductor devices.

Example implementations in various levels of detail are discussed below with reference to the associated figures. The discussion below first sets forth an example operating environment and then describes example hardware, schemes, and techniques. Example methods are described thereafter with reference to flow charts or diagrams.

### Example Environment

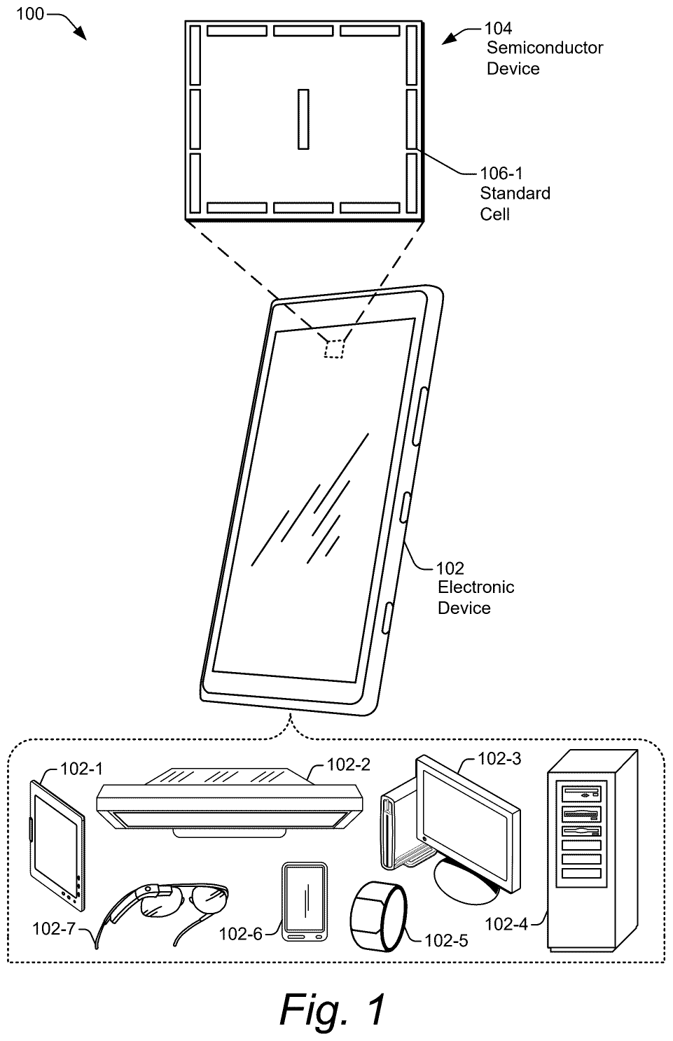

FIG. 1 illustrates an example electronic device 102 with a semiconductor device 104 (e.g., an integrated circuit) configured for fault detection. In this example, the electronic device 102 is depicted as a smartphone. However, the electronic device 102 may be implemented as any suitable computing or electronic device, such as a mobile communication device, modem, cellular or mobile phone, mobile station, gaming device, navigation device, media or entertainment device (e.g., a media streamer or gaming controller), laptop computer, desktop computer, tablet computer, smart appliance, vehicle-based electronic system, wearable computing device (e.g., clothing or watch), Internet of Things (IoTs) device, electronic portion of a machine or some equipment, server computer or portion thereof (e.g., a server blade), and the like. Illustrated examples of the electronic device 102 include a tablet device 102-1, a smart television 102-2, a desktop computer 102-3, a server computer 102-4, a smartwatch 102-5, a smartphone or document reader 102-6, and intelligent glasses 102-7.

In example implementations, the electronic device 102 includes at least one semiconductor device 104. The semiconductor device 104 may be a discrete device (e.g., diode, transistor), an optical device (e.g., light-emitting diodes), a microwave device, a sensor, a general-purpose processor, a security IC, a memory chip, a communications IC (e.g., that performs encryption or decryption on information being transmitted or received), or the like. The semiconductor device 104 includes a standard cell 106-1 (e.g., a macro) that facilitates detection and localization of defects. In implementations, the standard cell 106-1 includes a physical, design-for-test (DFT) structure interfaceable with, for example, a joint test action group (JTAG) test data register (TDR). A size, a shape, and a location of the standard cell 106-1 are shown for illustrative purposes and may be varied as would be appreciated by one of ordinary skill in the art having the benefit of this disclosure.

As illustrated in FIG. 1, for example only and not by way of limitation, the semiconductor device 104 includes twelve standard cells 106 positioned on an edge and a geometric center of the semiconductor device 104 (e.g., on a semiconductor die edge, on a semiconductor die center). A number of standard cells 106 may be varied based on a size and/or space constraints of a semiconductor device (e.g., semiconductor device 104). Further, the standard cells 106 can be positioned at any preferred location on a semiconductor device to detect faults, including cracks, scratches, delamination, and the like. In additional examples (not illustrated), a semiconductor device includes sixteen standard cells (e.g., standard cells 106) horizontally distributed (e.g., equivalently) across a surface of the semiconductor device.

### Example Schemes, Techniques, and Hardware Directed at Semiconductor Fault Detection

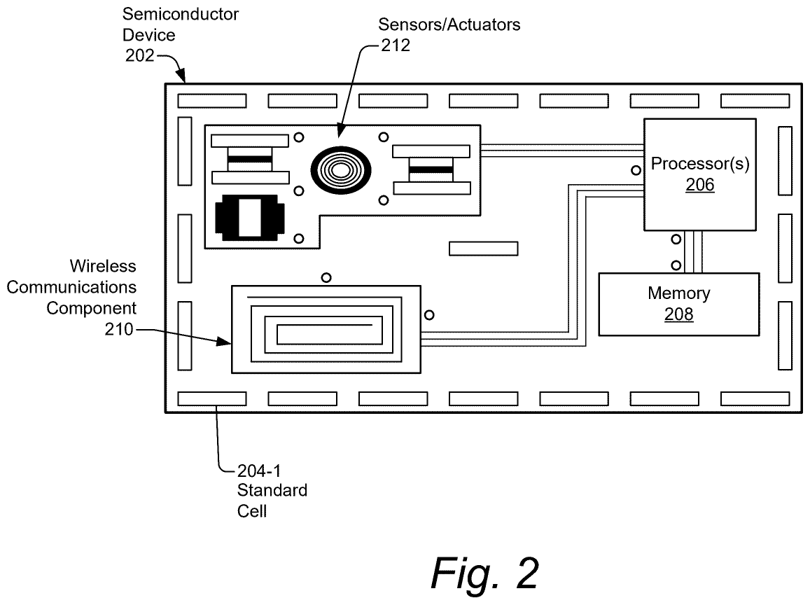

FIG. 2 illustrates an example semiconductor device 202 that includes a plurality of standard cells 204 and additional hardware elements. As illustrated, for example only and not by way of limitation, the example semiconductor device 202 is a system-on-chip (SoC) having a plurality of hardware elements (e.g., digital blocks). The hardware elements may include one or more processors 206, memory 208, a wireless communications component 210, and one or more sensors and/or actuators 212 (sensors/actuators 212). One or more standard cells of the plurality of standard cells 204 may be distributed across a surface of the semiconductor device 202 (e.g., in proximity to a failure prone zone, such as a die edge). For example, twenty standard cells of the plurality of standard cells 204 are disposed around edges of the semiconductor device 202 and one standard cell of the plurality of standard cells 204 is disposed in a center of the semiconductor device 202.

In implementations, the plurality of standard cells 204 are integrated in the semiconductor device 202 during fabrication and/or manufacturing. For example, components of the plurality of standard cells 204 can be deposited layer-by-layer during fabrication of the semiconductor device 202. In this way, the plurality of standard cells 204 can extend between two or more layers of the semiconductor device 202 to detect two- or three-dimensional faults on one or more layers.

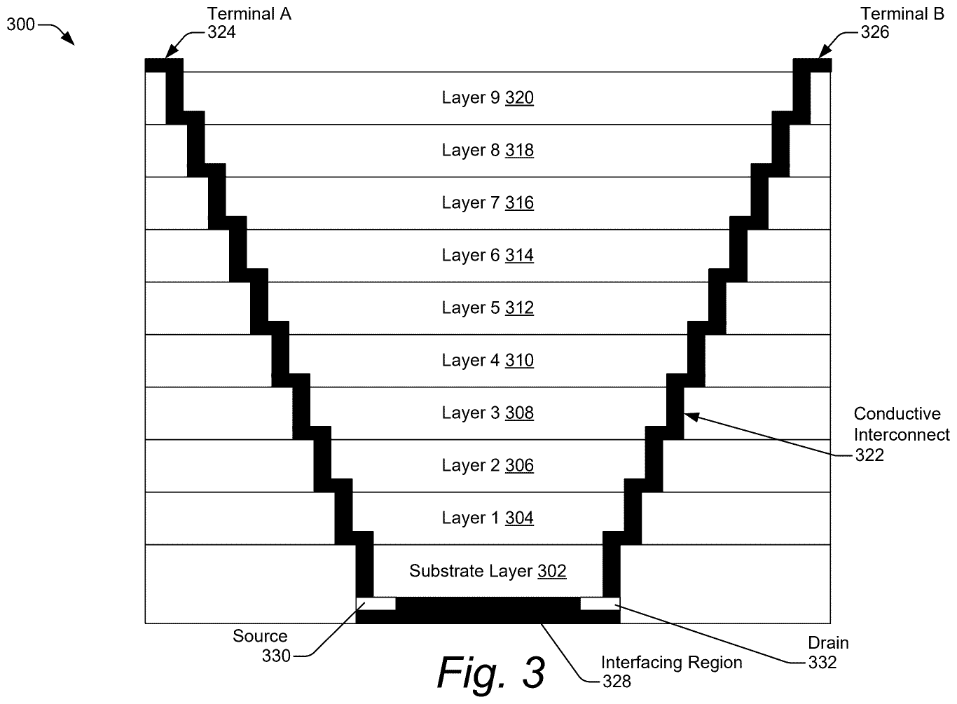

FIG. 3 illustrates an example partial, cross-sectional diagram 300 of stacked layers of an example semiconductor device (e.g., semiconductor device 104, semiconductor device 202) in accordance with one or more implementations. As illustrated, the stacked layers of the example semiconductor device include, for example only and not by way of limitation, a substrate layer 302, a first layer 304 (“Layer 1 304”), a second layer 306 (“Layer 2 306”), a third layer 308 (“Layer 3 308”), a fourth layer 310 (“Layer 4 310”), a fifth layer 312 (“Layer 5 312”), a sixth layer 314 (“Layer 6 314”), a seventh layer 316 (“Layer 7 316”), an eighth layer 318 (“Layer 8 318”), and a ninth layer 320 (“Layer 9 320”). Although a total of ten, substantially-parallel, and discrete stacked layers are illustrated, the semiconductor device can include more than or less than ten layers that are at least partially non-discrete and not parallel.

In implementations, the stacked layers (e.g., Layers 1-9) of the semiconductor device can include one or more of an epitaxial layer, an active layer, a gate oxide layer, a polysilicon layer, an isolation layer, an interconnect layer, a dielectric layer, a passivation layer, and a packaging layer. As an example, the substrate layer 302 may be a base layer (e.g., composed of silicon, gallium, or the like) upon which all other layers may be fabricated and may determine initial electrical characteristics of the semiconductor device. The epitaxial layer may be a layer of silicon (or other such material) grown on the substrate layer 302, providing a foundation for the formation of device structures for improved performance. The active layer may be a layer where active components, such as transistors, are formed. The gate oxide layer may be an insulating layer of silicon dioxide. The polysilicon layer (e.g., a gate electrode layer) may include polycrystalline silicon that forms gate terminals and/or interconnects. The isolation layer may be a layer (or layers) that electrically isolate components and/or other layers. The interconnect layer may include metal traces for electrically connecting different components. The dielectric layer may be a layer dedicated to insulating metal traces. The passivation layer may be a protective outer layer. The packaging layer may be a layer (e.g., composed of epoxy resin, solder, or conductive adhesive) that encapsulates the semiconductor device (e.g., the semiconductor die) for protection and connectivity. The packaging layer may be the physical and electrical interface between the semiconductor device and the external environment.

An example fabrication process of a semiconductor device typically begins with the substrate layer 302, usually a silicon wafer, which is prepared through processes such as slicing, polishing, and cleaning. The epitaxial layer may then be grown on the substrate layer using chemical vapor deposition (CVD) to create a high-quality crystalline surface. Next, the active layer may be formed through ion implantation or diffusion to introduce dopants, creating p-type or n-type regions as needed. The gate oxide layer can also be formed using thermal oxidation, where the silicon wafer is exposed to an oxidizing environment at high temperatures, producing a thin layer of silicon dioxide. Subsequently, the polysilicon gate layer can be deposited over the gate oxide layer using low-pressure chemical vapor deposition (LPCVD), and it is then doped to reduce its resistivity. Photolithography and etching techniques can be used to pattern these layers accurately. One or more interconnect layers, composed of metals such as aluminum or copper, may then be deposited using sputtering or electroplating and patterned to create the required circuit connections. One or more dielectric layers, typically silicon dioxide or silicon nitride, may be deposited via CVD to insulate different conducting layers. Then, the passivation layer can be applied to protect the surface of the semiconductor device (e.g., the semiconductor die) from environmental contamination and mechanical damage.

In implementations, during fabrication of the semiconductor device, at least one conductive interconnect 322 (e.g., starting at Terminal A 324 and extending to Terminal B 326) may be formed in two or more layers of the stacked layers of the semiconductor device. The at least one conductive interconnect 322 may include, for example, conductive pathways and an interfacing region 328 (e.g., a channel in the substrate layer 302, a resistor). The at least one conductive interconnect 322 may be formed in one or more layers of the stacked layers during fabrication of each respective layer of the one or more layers. As illustrated, the at least one conductive interconnect 322 extends from Terminal A 324 to Terminal B 326. Both Terminal A 324 and Terminal B 326 may be disposed on (or in) a topmost layer (e.g., a packaging layer). In at least some implementations, before fabrication of additional layers, Terminal A 324 and Terminal B 326 are disposed in a layer that may otherwise be stacked on top of before an end of fabrication, and a quality assurance of the semiconductor device (e.g., an incomplete semiconductor device, a semiconductor die) can be tested, using the at least one conductive interconnect 322, before completion of the fabrication. For example, before fabrication of the packaging layer, Terminal A 324 and Terminal B 326 can be disposed on (or in) at least one of the polysilicon layer, gate oxide layer, the active layer, or the epitaxial layer, and a fault detection can be performed using the at least one conductive interconnect 322 extending from Terminal A 324 to Terminal B 326. Thus, the at least one conductive interconnect 322 (i) operably connects (e.g., physically, electrically) Terminal A 324 and Terminal B 326 and (ii) extends through two or more stacked layers of a semiconductor device.

The interfacing region 328, implemented as a channel in the substrate layer 302 in the example of FIG. 3, can include a source 330 and a drain 332, both of which can connect (e.g., electrically, physically) to respective conductive pathways (e.g., a first conductive pathway extending from Terminal A 324 to the source 330, a second conductive pathway extending from Terminal B to the drain 332). In implementations, the conductive pathways and the interfacing region 328 include predetermined electrical properties, such as an electrical resistance. For example, the channel can include a resistance of 0 ohms, 5 microohms, 2 milliohms, or the like. If the semiconductor device includes a delamination, crack, or scratch (e.g., in a single layer, in multiple layers), then the at least one conductive interconnect 322 (e.g., a subcomponent of a standard cell, a subcomponent of a DFT structure) can be used to detect variations and/or subthreshold electrical properties (e.g., resistances, voltages, currents). For instance, if a crack is present in the semiconductor die in or between one or more layers, then at least one conductive pathway or the interfacing region 328 may be electrically disrupted, altering electrical properties of the at least one conductive interconnect 322. For example, if a measured or determined resistance between Terminal A 324 and Terminal B 326 differs from an expected resistance, then a fault can be detected. In another example, if a known voltage is applied at Terminal A 324 and an expected voltage is not measured or determined at Terminal B 326, then a fault can be detected.

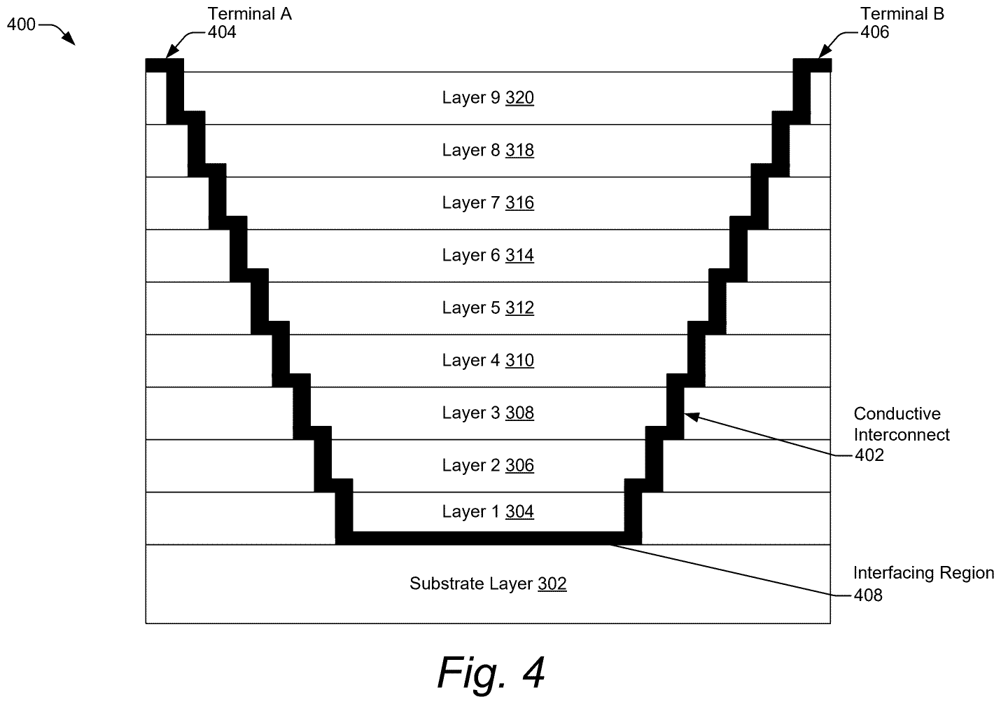

FIG. 4 illustrates another example partial, cross-sectional diagram 400 of stacked layers of an example semiconductor device (e.g., semiconductor device 104, semiconductor device 202) in accordance with one or more implementations. FIG. 4 is described in the context of FIGS. 1-3, and the partial, cross-sectional diagram 400 of FIG. 4 may include similar layers to that of the partial, cross-sectional diagram 300 of FIG. 3. As illustrated, at least one conductive interconnect 402 extends from Terminal A 404 to Terminal B 406 and the interfacing region 408 is disposed in layer (e.g., the first layer 304) above the substrate layer 302. Both Terminal A 404 and Terminal B 406 may be disposed on (or in) a topmost layer (e.g., the packaging layer). The at least one conductive interconnect 402 may include, for example, conductive pathways and an interfacing region 408 (e.g., a resistor, a capacitor, a logic cell, a channel). The at least one conductive interconnect 402 may be formed in one or more layers of the stacked layers during fabrication of each respective layer of the one or more layers. Moreover, in at least some implementations, before fabrication of additional layers, Terminal A 404 and Terminal B 406 are disposed in a layer that may otherwise be stacked on top of before an end of fabrication, and a quality assurance of the semiconductor device (e.g., an incomplete semiconductor device, a semiconductor die) can be tested, using the at least one conductive interconnect 402, before completion of a fabrication. For example, before fabrication of at least one of the isolation layer, the interconnect layer, the dielectric layer, the passivation layer, or the packaging layer, Terminal A 404 and Terminal B 406 can be disposed on (or in) at least one of the polysilicon layer, the gate oxide layer, the active layer, or the epitaxial layer, and a fault detection can be performed using the at least one conductive interconnect 402 extending from Terminal A 404 to Terminal B 406.

In implementations, the interfacing region 408 is at least partially conductive and can be formed, as illustrated in FIG. 4, in any layer (e.g., the first layer 304) above the substrate layer 302, such as the epitaxial layer. Further, the interfacing region 408 may be disposed at a topmost portion or a bottommost portion (opposite the topmost portion) of a given layer. The interfacing region 408 may include predetermined electrical properties, such as an electrical resistance. For example, the interfacing region 408 may include a resistance of 0 ohms, 5 microohms, 2 milliohms, or the like. If the semiconductor device includes a delamination, crack, or scratch (e.g., in a single layer, in multiple layers), then the at least one conductive interconnect 402 (e.g., a subcomponent of a standard cell, a subcomponent of a DFT structure) can be used to detect variations and/or subthreshold electrical properties (e.g., resistances, voltages, currents). For instance, if a crack is present in the semiconductor die in or between one or more layers, then at least one conductive pathway or the interfacing region 408 may be electrically disrupted, altering electrical properties of the at least one conductive interconnect 402. For example, if a measured or determined resistance between Terminal A 404 and Terminal B 406 differs from an expected resistance, then a fault can be detected. In another example, if a known voltage is applied at Terminal A 404 and an expected voltage is not measured or determined at Terminal B 406, then a fault can be detected.

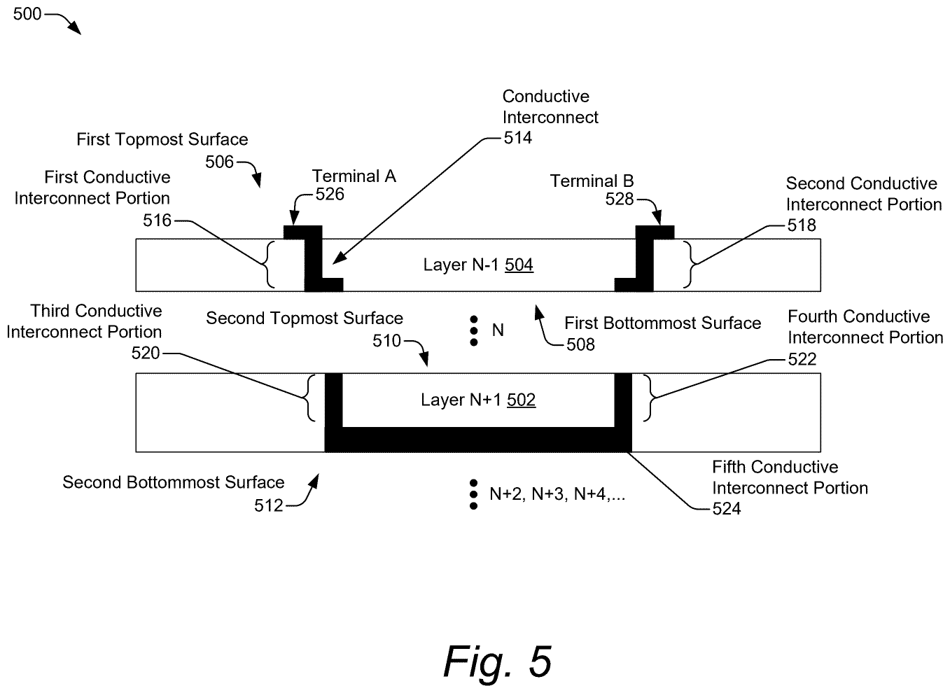

FIG. 5 illustrates a still further example partial, cross-sectional diagram 500 of stacked layers of an example semiconductor device (e.g., semiconductor device 104, semiconductor device 202) in accordance with one or more implementations. As illustrated, the stacked layers includes at least two layers (e.g., Layer N+1 502, Layer N−1) and may include any number of layers N between those two layers. Layer N+1 502 may also be stacked on any number of layers (N+2, N+3, N+4, . . . ). Layer N+1 (e.g., a first semiconductor layer, a topmost layer of the stacked layers) includes a first topmost surface 506 and an opposing first bottommost surface 508. Layer N+1 (e.g., a second semiconductor layer, a bottommost layer of the stacked layers) includes a second topmost surface 510 and a second bottommost surface 512. A conductive interconnect 514 can extend through the at least two layers of the semiconductor device. The conductive interconnect 514 includes a first conductive interconnect portion 516, a second conductive interconnect portion 518, a third conductive interconnect portion 520, a fourth conductive interconnect portion 522, and a fifth conductive interconnect portion 524 (e.g., an interfacing region 408). The first conductive interconnect portion 516 can be configured to be in electrical communication (e.g., physical connection, electrical coupling) with Terminal A 526 and the third conductive interconnect portion 520. The first conductive interconnect portion 516 and the third conductive interconnect portion 520 define a first conductive pathway. The second conductive interconnect portion 518 can be configured to be in electrical communication with Terminal B 528 and the fourth conductive interconnect portion 522. The second conductive interconnect portion 518 and the fourth conductive interconnect portion 522 define a second conductive pathway. The third conductive interconnect portion 520 and fourth conductive interconnect portion 522 can further be configured to be in electrical communication with the fifth conductive interconnect portion 524.

In implementations, the fifth conductive interconnect portion 524 can be disposed proximate to the second bottommost surface 512 (as illustrated in FIG. 5) or the second topmost surface 510 (not illustrated). In the latter implementation, the conductive interconnect 514 still includes the third conductive interconnect portion 520 and fourth conductive interconnect portion 522 regardless of size. The third conductive interconnect portion 520 and fourth conductive interconnect portion 522 may (i) include any conductive or semi-conductive material that interfaces between the first conductive interconnect portion 516 and the second conductive interconnect portion 518 or (ii) be integral to the fifth conductive interconnect portion 524 (e.g., a source or a drain of a channel). The fifth conductive interconnect portion 524 may be composed of similar material to that of the first conductive interconnect portion 516, the second conductive interconnect portion 518, the third conductive interconnect portion 520, and fourth conductive interconnect portion 522 or it can be composed of dissimilar materials and/or function electrically different than one or more of the aforementioned portions (e.g., an interfacing region).

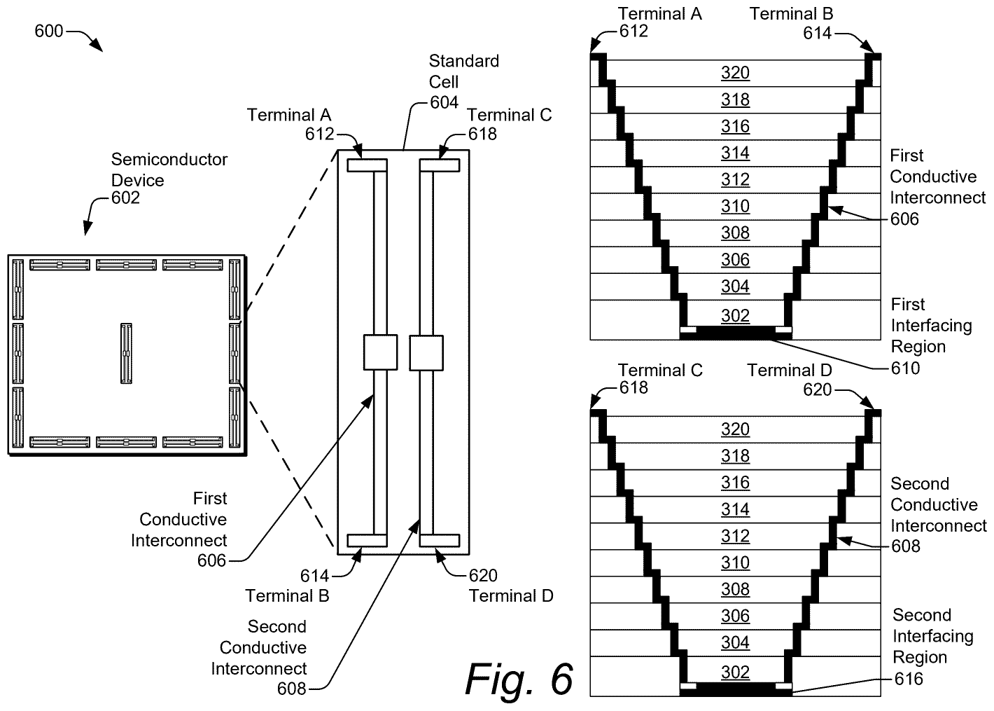

FIG. 6 illustrates an example implementation 600 of an example standard cell (e.g., standard cell 106-1) in accordance with one or more implementations. FIG. 6 is described in the context of FIGS. 1-5 and contains similar components and layers. As illustrated, a semiconductor device 602 (e.g., semiconductor device 104, semiconductor device 202) includes a standard cell 604 (e.g., a DFT structure). The standard cell 604 may include a first conductive interconnect 606 and a second conductive interconnect 608, which, in at least some implementations are positioned substantially parallel to each other in at least one dimension. The first conductive interconnect 606 includes a first interfacing region 610 that connects conductive pathways between Terminal A 612 and Terminal B 614. The second conductive interconnect 608 includes a second interfacing region 616 that connects conductive pathways between Terminal C 618 and Terminal D 620. Although FIG. 6 illustrates the first interfacing region 610 and the second interfacing region 616 as being disposed in the substrate layer 302, either or both of the first interfacing region 610 and the second interfacing region 616 can be disposed in a different layer (e.g., the active layer 306), similar to the interfacing region 408 from FIG. 4.

In such an implementation, the standard cell 604 can detect two- or three-dimensional faults in one or more layers of the stacked layers. For example, the standard cell 604, implemented as a DFT structure, can be operably coupled to a JTAG TDR and tested for fault detection. In one example, the semiconductor device 602 includes a fault in one or more layers of the stacked layers that extends perpendicular or parallel to a plane defined by a length of the first conductive interconnect 606 and/or the second conductive interconnect 608. Upon applying a high voltage, for example, at Terminal A 612, Terminal C 618 and/or Terminal D 620 of the standard cell 604 may be measured having a high voltage (e.g. with respect to Terminal D 620 or Terminal C 618, respectively, or with respect to a reference voltage), which may indicate a short circuit and, therefore, a fault in the semiconductor device 602. In another example, the semiconductor device 602 includes a fault in one or more layers of the stacked layers that intersects the first conductive interconnect 606 and/or the second conductive interconnect 608. Upon applying a high voltage, for example, at Terminal A 612 and/or Terminal C 618, Terminal B 614 and/or Terminal D 620 may be measured having a low voltage (e.g., with respect to Terminal A 612, Terminal C 618, or a reference voltage), which may indicate an open circuit and, therefore, a fault in the semiconductor device 602.

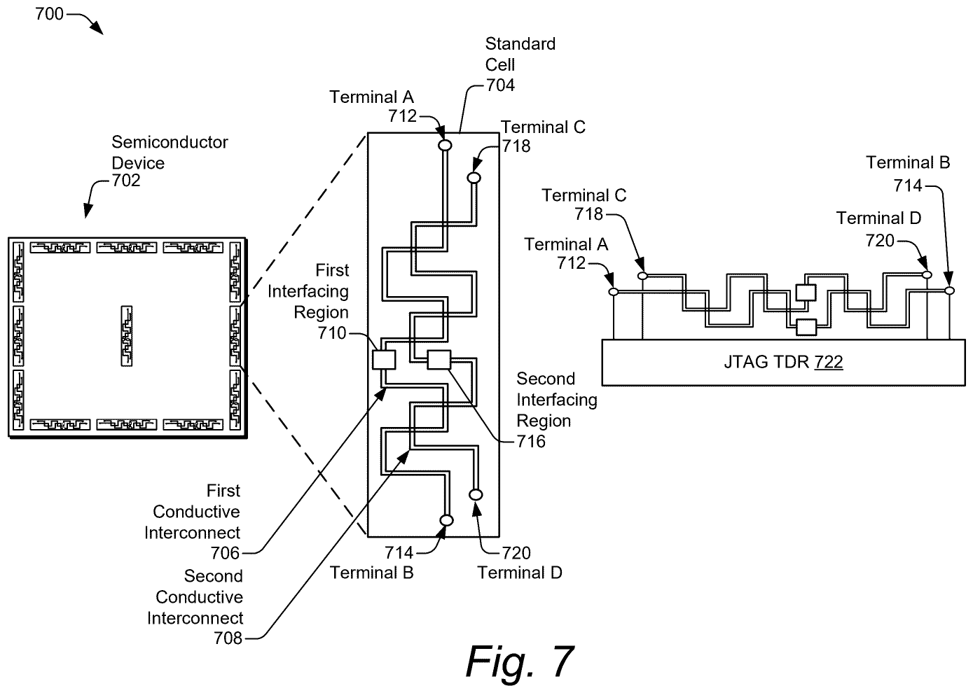

FIG. 7 illustrates an example implementation 700 of an example standard cell (e.g., standard cell 106-1) in accordance with one or more implementations. FIG. 7 is described in the context of FIGS. 1-5. As illustrated, a semiconductor device 702 (e.g., semiconductor device 104, semiconductor device 202) includes a standard cell 704 (e.g., a DFT structure) having a first conductive interconnect 706 and a second conductive interconnect 708 configured in an intertwined serpentine structure. The first conductive interconnect 706 includes a first interfacing region 710 that connects conductive pathways between Terminal A 712 and Terminal B 714. The second conductive interconnect 708 includes a second interfacing region 716 that connects conductive pathways between Terminal C 718 and Terminal D 720. The first interfacing region 710 and/or the second interfacing region 716 may be disposed in the substrate layer 302 (not illustrated) or an altogether a different layer (e.g., the active layer 306), similar to the interfacing region 408 from FIG. 4.

In implementations, the standard cell 504 having the first conductive interconnect 706 and a second conductive interconnect 708 configured in the intertwined serpentine structure can enable detection of two- or three-dimensional faults in one or more layers of the stacked layers and extending between two or more layers of the stacked layers. In the intertwined serpentine structure, the first conductive interconnect 706 and the second conductive interconnect 708 may be positioned at different layers within the stacked layers and may be routed to overlap each other at one or more points. For instance, the first conductive interconnect 706 and the second conductive interconnect 708 may be routed to intersect in such a manner that their projections coincide at one or more common points with a planar coordinate system (e.g., a plane parallel with one or more layers), while being disposed in different layers. As an example, the first conductive interconnect 706 can be positioned in a first layer, while a second conductive interconnect 708 is positioned in a second layer. The first conductive interconnect 706 may be routed to extend down two or more layers (e.g., a layer closer in proximity to the substrate layer 302) to a third layer and be routed in proximity (e.g., beneath) to the second conductive interconnect 708 in the second layer. In this way, the second conductive interconnect 708 in the second layer and the first conductive interconnect in the third layer may be electrically coupled if a fault extends between the second layer and the third layer.

For example, the standard cell 704, implemented as a DFT structure, can be operably coupled to a JTAG TDR 722 and tested for fault detection. In one example, the semiconductor device 702 includes a fault in one or more layers of the stacked layers that extends perpendicular or parallel to a plane defined by a length of the first conductive interconnect 706 and/or the second conductive interconnect 708. Upon applying a high voltage, for example, at Terminal A 712, Terminal C 718 and/or Terminal D 720 of the standard cell 704 may be measured having a high voltage, which may indicate a short circuit and, therefore, a fault in the semiconductor device 702. In another example, upon applying a high voltage at Terminal D 720, Terminal A 712 and/or Terminal B 714 of the standard cell 704 may be measured having a high voltage (e.g., with respect to a reference voltage, with respect to each other), which may indicate a short circuit and, therefore, a fault in the semiconductor device 702. In still another example, the semiconductor device 702 includes a fault in one or more layers of the stacked layers that intersects the first conductive interconnect 706 and/or the second conductive interconnect 708. Upon applying a high voltage, for example, at Terminal A 712 and/or Terminal C 718, Terminal B 714 and/or Terminal D 720 may be measured having a low voltage (e.g., with respect to Terminal A 712, Terminal C 718, or a reference voltage), which may indicate an open circuit and, therefore, a fault in the semiconductor device 702. In a still further example, the semiconductor device 702 includes a fault in one or more layers of the stacked layers that extends between the first conductive interconnect 706 positioned in a first layer and the second conductive interconnect 708 positioned in a second layer. The first layer may be at a higher or lower layer than the second layer. Upon applying a high voltage, for example, at Terminal A 712, Terminal C 718 and/or Terminal D 720 may be measured having a high voltage, which may indicate a short circuit and, therefore, a fault in the semiconductor device 702. Using the intertwined serpentine structure, the first conductive interconnect 706 and the second conductive interconnect 708 can be interwoven in underlying metal layers for additional detection of inter- and intra-shorts and, therefore, additional fault detection.

In implementations, one or more standard cells (e.g., standard cell 604, standard cell 704) of a semiconductor device (e.g., semiconductor device 602, semiconductor device 702) can operably coupled to a JTAG TDR (e.g., JTAG TDR 722) and addressed through a register, enabling electrical properties (e.g., resistances, voltages, currents) to be measured and/or determined. Depending on which standard cell of the one or more standard cells returns unexpected or undesirable results, a fault can be detected and a precise location in (or on) the semiconductor device can be identified, enabling accelerated analysis (e.g., failure analysis (FA) debug), quicker diagnosis (e.g., of the type of fault, a location of a fault), improved post-reliability stress test inspection, and yield improvement. Moreover, utilization of these standard cells enables detection of micro- and/or nano-scale faults, whereas traditional FA tools rely on physical anomaly detection. A width and a spacing of the standard cells on (or in) the semiconductor device can be adjusted based on space constraints of the semiconductor device.

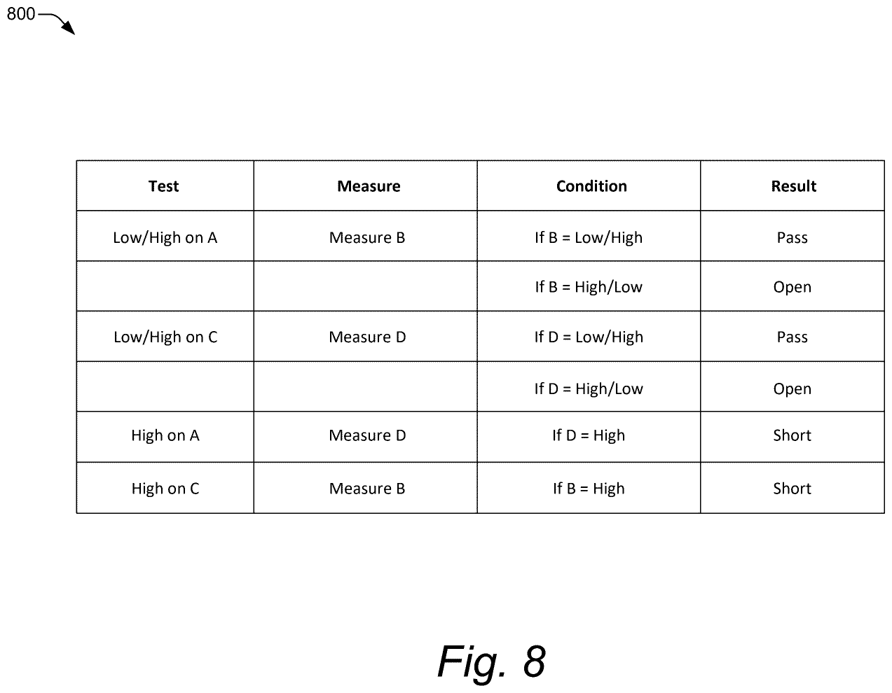

FIG. 8 illustrates an example test procedure table 800 for a standard cell of a semiconductor device to detect faults. In aspects, the example test procedure table 800 may be applicable for the standard cell 604 of FIG. 6 and/or the standard cell 704 of FIG. 7. The standard cell may be operably coupled to a JTAG TDR (e.g., JTAG TDR 722) and addressed through a register, enabling electrical properties (e.g., resistances, voltages, currents) to be measured and/or determined. As illustrated, for example only and not by way of limitation, the JTAG TDR may apply, first, a low voltage and, then, a high voltage on Terminal A (e.g., Terminal A 612, Terminal A 712). The JTAG TDR may measure Terminal B (e.g., Terminal B 614, Terminal B 714). If the JTAG TDR measures, first, a low voltage and, then, a high voltage on Terminal B (e.g., with corresponding and/or expected electrical values accounting for the presence or absence of a known resistance), then JTAG TDR may not detect a fault (“Pass”). If, however, the JTAG TDR measures, first, a high voltage and/or, then, a low voltage at Terminal B, then the JTAG RDR may detect a fault (e.g., an open circuit).

In another test, the JTAG TDR may apply, first, a low voltage and, then, a high voltage on Terminal C (e.g., Terminal C 618, Terminal C 718). The JTAG TDR may measure Terminal D (e.g., Terminal D 620, Terminal D 720). If the JTAG TDR measures, first, a low voltage and, then, a high voltage on Terminal D (e.g., with corresponding and/or expected electrical values accounting for the presence or absence of a known resistance), then the JTAG TDR may not detect a fault (“Pass). If, however, the JTAG TDR measures, first, a high voltage and/or, then, a low voltage at Terminal D, then the JTAG RDR may detect a fault (e.g., an open circuit).

In still another test, the JTAG TDR may apply a high voltage at Terminal A and measure Terminal D. If Terminal D measures a high voltage, then the JTAG TDR may detect a fault (e.g., a short circuit). In a still further test, the JTAG TDR may apply a high voltage at Terminal C and measure Terminal B. If Terminal B measure a high voltage, then the JTAG TDR may detect a fault (e.g., a short circuit).

### Example Electronic Device

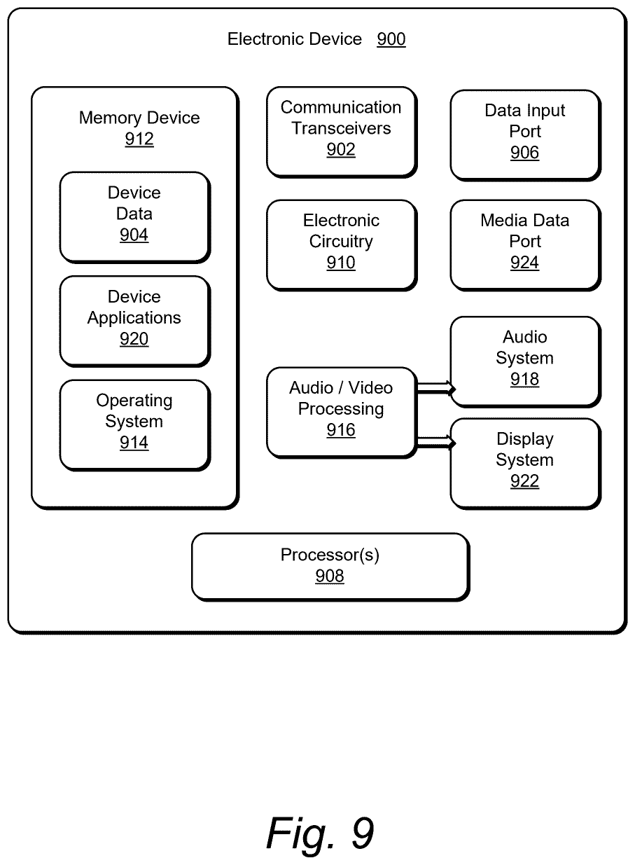

FIG. 9 illustrates various components of an example electronic device 900 (e.g., electronic device 102) that can include a semiconductor configured for fault detection in accordance with one or more described aspects. The electronic device 900 may be implemented as any one or combination of a fixed, mobile, stand-alone, or embedded device; in any form of a consumer, computer, portable, user, server, communication, phone, navigation, gaming, audio, camera, messaging, media playback, and/or other type of electronic device 900, such as the smartphone that is depicted FIG. 1 as the electronic device 102.

The electronic device 900 can include one or more communication transceivers 902 that enable wired and/or wireless communication of device data 904, such as received data, transmitted data, or other information as described above. Example communication transceivers 902 include NFC transceivers, wireless personal area network (PAN) (WPAN) radios compliant with various IEEE 802.15 (Bluetooth™) standards, wireless local area network (LAN) (WLAN) radios compliant with any of various IEEE 802.8 (Wi-Fi™) standards, wireless wide area network (WAN) (WWAN) radios (e.g., those that are 3GPP-compliant) for cellular telephony, wireless metropolitan area network (MAN) (WMAN) radios compliant with various IEEE 802.16 (WiMAX™) standards, infrared (IR) transceivers compliant with an Infrared Data Association (IrDA) protocol, and wired local area network (LAN) Ethernet transceivers.

The electronic device 900 may also include one or more data input ports 906 via which any type of data, media content, and/or other inputs can be received, such as user-selectable inputs, messages, applications, music, television content, recorded video content, and any other type of audio, video, and/or image data received from any content and/or data source. The data input ports 906 may include USB ports, coaxial cable ports, fiber optic ports for optical fiber interconnects or cabling, and other serial or parallel connectors (including internal connectors) for flash memory, DVDs, CDs, and the like. These data input ports 906 may be used to couple the electronic device 900 to components, peripherals, or accessories such as keyboards, microphones, cameras, or other sensors.

The electronic device 900 of this example includes at least one processor 908 (e.g., any one or more of application processors, microprocessors, digital-signal processors (DSPs), controllers, and the like), which can include a combined processor and memory system (e.g., implemented as part of an SoC), that processes (e.g., executes) computer-executable instructions to control operation of the device. The processor 908 may be implemented as an application processor, embedded controller, microcontroller, security processor, and the like. Generally, a processor or processing system may be implemented at least partially in hardware, which can include components of an integrated circuit or on-chip system, a digital-signal processor (DSP), an application-specific integrated circuit (ASIC), a field-programmable gate array (FPGA), a complex programmable logic device (CPLD), and other implementations in silicon and/or other materials.

Alternatively or additionally, the electronic device 900 can be implemented with any one or combination of electronic circuitry, which may include software, hardware, firmware, or fixed logic circuitry that is implemented in connection with processing and control circuits, which are generally indicated at 910 (as electronic circuitry 910). This electronic circuitry 910 can implement executable or hardware-based modules (not shown in FIG. 9), such as through processing/computer-executable instructions stored on computer-readable media, through logic circuitry and/or hardware (e.g., such as an FPGA), and so forth.

Although not shown, the electronic device 900 can include a system bus, interconnect, crossbar, or data transfer system that couples the various components within the device 900. A system bus or interconnect can include any one or a combination of different bus structures, such as a memory bus or memory controller, a peripheral bus, a universal serial bus, and/or a processor or local bus that utilizes any of a variety of bus architectures.

The electronic device 900 also includes one or more memory devices 912 that enable data storage, examples of which include random access memory (RAM), non-volatile memory (e.g., read-only memory (ROM), flash memory, EPROM, and EEPROM), and a disk storage device. Thus, the memory device(s) 912 can be distributed across different logical storage levels of a system as well as at different physical components. The memory device(s) 912 provide data storage mechanisms to store the device data 904, other types of code and/or data, and various device applications 920 (e.g., software applications or programs). For example, an operating system 914 can be maintained as software instructions within the memory device 912 and executed by the processor 908.

In some implementations, the electronic device 900 also includes an audio and/or video processing system 916 that processes audio data and/or passes through the audio and video data to an audio system 918 and/or to a display system 922 (e.g., a video buffer or a screen of a smartphone or camera). The audio system 918 and/or the display system 922 may include any devices that process, display, and/or otherwise render audio, video, display, and/or image data. Display data and audio signals can be communicated to an audio component and/or to a display component via an RF (radio frequency) link, S-video link, HDMI (high-definition multimedia interface), composite video link, component video link, DVI (digital video interface), analog audio connection, or other similar communication link, such as a media data port 924. In some implementations, the audio system 918 and/or the display system 922 are external or separate components of the electronic device 900. Alternatively, the display system 922 can be an integrated component of the example electronic device 900, such as part of an integrated touch interface.

The electronic device 900 of FIG. 9 is an example implementation of the electronic device 102 of FIG. 1. One or more of the aforementioned components of the electronic device 900 may be constructed with a semiconductor device (e.g., semiconductor device 104, semiconductor device 602, semiconductor device 702) that has one or more standard cells (e.g., standard cell 106-1, standard cell 204-1, standard cell 604, standard cell 704) for fault detection. For example, the one or more of the processor(s) 908, the memory device 912, the communication transceivers 902, the audio/video processing 916, etc. may be implemented on a semiconductor device (e.g., an SoC) configured with one or more standard cells for fault detection.

### Additional Examples

In the following section, additional examples are provided.

Example 1: A semiconductor device comprising: two or more stacked layers, the two or more stacked layers comprising: a first semiconductor layer having: a topmost surface; a bottommost surface opposite the topmost surface; a first electrical terminal electrically accessible at the topmost surface; a second electrical terminal electrically accessible at the topmost surface; a first conductive interconnect portion, the first conductive interconnect portion configured to be in electrical communication with the first electrical terminal and extending, from the first electrical terminal and through the first semiconductor layer, to the bottommost surface; and a second conductive interconnect portion, the second conductive interconnect portion configured to be in electrical communication with the second electrical terminal and extending, from the second electrical terminal and through the first semiconductor layer, to the bottommost surface; and a second semiconductor layer having: a second topmost surface; a second bottommost surface opposite the second topmost surface of the second semiconductor layer and opposite the topmost surface of the first semiconductor layer; a third conductive interconnect portion, the third conductive interconnect portion configured to be in electrical communication with the first conductive interconnect portion and electrically extending from the first conductive interconnect portion and into at least a portion of the second semiconductor layer; a fourth conductive interconnect portion, the fourth conductive interconnect portion configured to be in electrical communication with the second conductive interconnect portion and electrically extending from the second conductive interconnect portion and into at least a second portion of the second semiconductor layer; a fifth conductive interconnect portion, the fifth conductive interconnect portion configured to be in electrical communication with the third conductive interconnect portion and the fourth conductive interconnect portion; and, a first conductive interconnect comprising the first conductive interconnect portion, the second conductive interconnect portion, the third conductive interconnect portion, the fourth conductive interconnect portion, and the fifth conductive interconnect portion, the first conductive interconnect usable to localize a fault in the semiconductor device.

Example 2: The semiconductor device of example 1, wherein: the first conductive interconnect comprises (i) a first electrical property based on an absence of the fault in the semiconductor device or (ii) a second electrical property based on a presence of the fault in the semiconductor device. For example, the first conductive interconnect may exhibit the first electrical property in the absence of the fault, and may exhibit the second electrical property in the present of the fault.

Example 3: The semiconductor device of example 2 or 3, wherein the first electrical property is a first resistance within a range, the second electrical property is a second resistance outside of the range.

Example 4: The semiconductor device of example 3, wherein: a first measured electrical value at the first electrical terminal or the second electrical terminal is sufficient to indicate the first electrical property or the second electrical property and the absence of the fault in the semiconductor device or the presence of the fault in the semiconductor device, respectively.

Example 5: The semiconductor device of example 2, wherein a first measured electrical value at the first electrical terminal or the second electrical terminal is sufficient to indicate the first electrical property or the second electrical property and the absence of the fault in the semiconductor device or the presence of the fault in the semiconductor device, respectively. For example, the first conductive interconnect may be configured such that the first electrical property and the second electrical property may be determined by taking a first measured electrical value at the first electrical terminal or the second electrical terminal.

Example 6: The semiconductor device of example 5, wherein the first measured electrical value is a voltage between the first electrical terminal and at least one of the second electrical terminal or a reference voltage.

Example 7: The semiconductor device of example 1, wherein: the first semiconductor layer further comprises a third electrical terminal and a fourth electrical terminal; and the semiconductor device further comprises a second conductive interconnect, the second conductive interconnect connecting the third electrical terminal to the fourth electrical terminal.

Example 8: The semiconductor device of example 7, wherein the first conductive interconnect and the second conductive interconnect are included in a design-for-test structure, the first conductive interconnect and the second conductive interconnect positioned substantially parallel to each other in at least one dimension.

Example 9: The semiconductor device of example 8, wherein the first conductive interconnect and the second conductive interconnect are (i) electrically isolated based on an absence of the fault in the semiconductor device or (ii) electrically coupled based on a presence of the fault, the fault extending in a respective layer of the two or more stacked layers of the semiconductor device between the first conductive interconnect and the second conductive interconnect.

Example 10: The semiconductor device of example 9, wherein a second measured electrical value at the first electrical terminal, the second electrical terminal, the third electrical terminal, or the fourth electrical terminal is sufficient to indicate the electrical isolation or the electrical coupling and the absence of the fault in the semiconductor device or the presence of the fault in the semiconductor device, respectively.

Example 11: The semiconductor device of example 10, wherein the second measured electrical value is a voltage between at least one of the first electrical terminal, the second electrical terminal, the third electrical terminal, or the fourth electrical terminal and another electrical terminal or a reference voltage.

Example 12: The semiconductor device of example 7, wherein: the first conductive interconnect and the second conductive interconnect are integrated into a design-for-test structure; and the first conductive interconnect and the second conductive interconnect are configured such that at least one of the first conductive interconnect or the second conductive interconnect overlaps the other at least once while in different layers of the two or more stacked layers.

Example 13: The semiconductor device of example 12, wherein the first conductive interconnect and the second conductive interconnect are configured in an intertwined serpentine structure.

Example 14: The semiconductor device of example 13, wherein the first conductive interconnect and the second conductive interconnect are (i) electrically isolated in an absence of the fault in the semiconductor device or (ii) electrically coupled based on a presence of the fault, the fault extending: in a respective layer of the two or more stacked layers of the semiconductor device between the first conductive interconnect and the second conductive interconnect, or between at least two layers of the two or more stacked layers of the semiconductor device between the first conductive interconnect and the second conductive interconnect.

Example 15: The semiconductor device of example 12, wherein the first conductive interconnect and the second conductive interconnect are (i) electrically isolated in an absence of the fault in the semiconductor device or (ii) electrically coupled based on a presence of the fault, the fault extending: in a respective layer of the two or more stacked layers of the semiconductor device between the first conductive interconnect and the second conductive interconnect, or between at least two layers of the two or more stacked layers of the semiconductor device between the first conductive interconnect and the second conductive interconnect.

Example 16: The semiconductor device of example 15, wherein a third measured electrical value at the first electrical terminal, the second electrical terminal, the third electrical terminal, or the fourth electrical terminal is sufficient to indicate the electrical isolation or the electrical coupling and the absence of the fault in the semiconductor device or the presence of the fault in the semiconductor device, respectively.

Example 17: The semiconductor device of example 16, wherein the third measured electrical value is a voltage between at least one of the first electrical terminal, the second electrical terminal, the third electrical terminal, or the fourth electrical terminal and another electrical terminal or a reference voltage.

Example 18: The semiconductor device of example 1, the fifth conductive interconnect portion comprises an interfacing region, the interfacing region being at least one of a resistor, a capacitor, a logic cell, or a channel.

Example 19: The semiconductor device of example 18, wherein the interfacing region comprises a resistance of at least one of 0 ohms, 5 microohms, or 2 milliohms.

Example 20: The semiconductor device of example 18, wherein: the first layer and the second layer of the two or more stacked layers comprise a substrate layer and an active layer, respectively; and the interfacing region comprises the channel, the channel disposed in the substrate layer.

Example 21: A semiconductor device comprising: two or more stacked layers, the two or more stacked layer comprising a substrate layer and a transistor layer; and at least one conductive interconnect that connects a first electrical terminal to a second electrical terminal, the at least one conductive interconnect extending between a first layer of the two or more stacked layers and a second layer of the two or more stacked layers.

Example 22: The semiconductor device of example 21, wherein the at least on conductive interconnect connects the first electrical terminal to the second electrical terminal and a third electrical terminal.

Example 23: The semiconductor device of example 21, wherein an electrical connectivity of the at least one conductive interconnect is disrupted at a location corresponding to a physical defect.

Example 24: The semiconductor device of example 21, wherein a first conductive interconnect of the at least one conductive interconnect is operatively coupled to a second conductive interconnect of the at least one conductive interconnect via a resistor, an inductor, an inverter, a capacitor, a logic cell, or a substrate material.

Example 25: The semiconductor device of example 24, wherein the resistor comprises at least one of 0 Ohms, 5 microOhms, or 2 milliOhms.

Example 26: The semiconductor device of example 21, wherein the first layer of the two or more stacked layers comprises the transistor layer and the second layer of the two or more stacked layers comprises the substrate layer.

### CONCLUSION

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations directed at semiconductor fault detection have been described in language specific to certain features and/or methods, the subject of the appended claims is not necessarily limited to the specific features or methods described. Rather, the specific features and methods are disclosed as example implementations directed at semiconductor fault detection.

What is claimed is:

1. A semiconductor device comprising:
two or more stacked layers, the two or more stacked layers comprising:
a first semiconductor layer having:
a topmost surface;
a bottommost surface opposite the topmost surface;
a first electrical terminal electrically accessible at the topmost surface;
a second electrical terminal electrically accessible at the topmost surface;
a first conductive interconnect portion, the first conductive interconnect portion configured to be in electrical communication with the first electrical terminal and extending, from the first electrical terminal and through the first semiconductor layer, to the bottommost surface; and
a second conductive interconnect portion, the second conductive interconnect portion configured to be in electrical communication with the second electrical terminal and extending, from the second electrical terminal and through the first semiconductor layer, to the bottommost surface;
a second semiconductor layer having:
a second topmost surface;
a second bottommost surface opposite the second topmost surface of the second semiconductor layer and opposite the topmost surface of the first semiconductor layer;
a third conductive interconnect portion, the third conductive interconnect portion configured to be in electrical communication with the first conductive interconnect portion and electrically extending from the first conductive interconnect portion and into at least a portion of the second semiconductor layer;
a fourth conductive interconnect portion, the fourth conductive interconnect portion configured to be in electrical communication with the second conductive interconnect portion and electrically extending from the second conductive interconnect portion and into at least a second portion of the second semiconductor layer; and
a fifth conductive interconnect portion, the fifth conductive interconnect portion configured to be in electrical communication with the third conductive interconnect portion and the fourth conductive interconnect portion; and
a first conductive interconnect comprising the first conductive interconnect portion, the second conductive interconnect portion, the third conductive interconnect portion, the fourth conductive interconnect portion, and the fifth conductive interconnect portion, the first conductive interconnect usable to localize a fault in the semiconductor device.

2. The semiconductor device of claim 1, wherein:
the first conductive interconnect comprises (i) a first electrical property based on an absence of the fault in the semiconductor device or (ii) a second electrical property based on a presence of the fault in the semiconductor device.

3. The semiconductor device of claim 2, wherein the first electrical property is a first resistance within a range, and the second electrical property is a second resistance outside of the range.

4. The semiconductor device of claim 3, wherein:
a first measured electrical value at the first electrical terminal or the second electrical terminal is sufficient to indicate the first electrical property or the second electrical property and the absence of the fault in the semiconductor device or the presence of the fault in the semiconductor device, respectively.

5. The semiconductor device of claim 2, wherein:
a first measured electrical value at the first electrical terminal or the second electrical terminal is sufficient to indicate the first electrical property or the second electrical property and the absence of the fault in the semiconductor device or the presence of the fault in the semiconductor device, respectively.

6. The semiconductor device of claim 5, wherein the first measured electrical value is a voltage between the first electrical terminal and at least one of the second electrical terminal or a reference voltage.

7. The semiconductor device of claim 1, wherein:
the first semiconductor layer further comprises a third electrical terminal and a fourth electrical terminal; and
the semiconductor device further comprises a second conductive interconnect, the second conductive interconnect connecting the third electrical terminal to the fourth electrical terminal.

8. The semiconductor device of claim 7, wherein the first conductive interconnect and the second conductive interconnect are included in a design-for-test structure, the first conductive interconnect and the second conductive interconnect positioned substantially parallel to each other in at least one dimension.

9. The semiconductor device of claim 8, wherein the first conductive interconnect and the second conductive interconnect are (i) electrically isolated based on an absence of the fault in the semiconductor device or (ii) electrically coupled based on a presence of the fault, the fault extending in a respective layer of the two or more stacked layers of the semiconductor device between the first conductive interconnect and the second conductive interconnect.

10. The semiconductor device of claim 9, wherein a second measured electrical value at the first electrical terminal, the second electrical terminal, the third electrical terminal, or the fourth electrical terminal is sufficient to indicate the electrical isolation or the electrical coupling and the absence of the fault in the semiconductor device or the presence of the fault in the semiconductor device, respectively.

11. The semiconductor device of claim 10, wherein the second measured electrical value is a voltage between at least one of the first electrical terminal, the second electrical terminal, the third electrical terminal, or the fourth electrical terminal and another electrical terminal or a reference voltage.

12. The semiconductor device of claim 7, wherein:
the first conductive interconnect and the second conductive interconnect are integrated into a design-for-test structure; and
the first conductive interconnect and the second conductive interconnect are configured such that at least one of the first conductive interconnect or the second conductive interconnect overlaps the other at least once while in different layers of the two or more stacked layers.

13. The semiconductor device of claim 12, wherein the first conductive interconnect and the second conductive interconnect are configured in an intertwined serpentine structure.

14. The semiconductor device of claim 13, wherein the first conductive interconnect and the second conductive interconnect are (i) electrically isolated in an absence of the fault in the semiconductor device or (ii) electrically coupled based on a presence of the fault, the fault extending:
in a respective layer of the two or more stacked layers of the semiconductor device between the first conductive interconnect and the second conductive interconnect, or
between at least two layers of the two or more stacked layers of the semiconductor device between the first conductive interconnect and the second conductive interconnect.

15. The semiconductor device of claim 12, wherein the first conductive interconnect and the second conductive interconnect are (i) electrically isolated in an absence of the fault in the semiconductor device or (ii) electrically coupled based on a presence of the fault, the fault extending:
in a respective layer of the two or more stacked layers of the semiconductor device between the first conductive interconnect and the second conductive interconnect, or
between at least two layers of the two or more stacked layers of the semiconductor device between the first conductive interconnect and the second conductive interconnect.

16. The semiconductor device of claim 15, wherein a third measured electrical value at the first electrical terminal, the second electrical terminal, the third electrical terminal, or the fourth electrical terminal is sufficient to indicate the electrical isolation or the electrical coupling and the absence of the fault in the semiconductor device or the presence of the fault in the semiconductor device, respectively.

17. The semiconductor device of claim 16, wherein the third measured electrical value is a voltage between at least one of the first electrical terminal, the second electrical terminal, the third electrical terminal, or the fourth electrical terminal and another electrical terminal or a reference voltage.

18. The semiconductor device of claim 1, wherein the fifth conductive interconnect portion comprises an interfacing region, the interfacing region being at least one of a resistor, a capacitor, a logic cell, or a channel.

19. The semiconductor device of claim 18, wherein the interfacing region comprises a resistance of at least one of 0 ohms, 5 microohms, or 2 milliohms.

20. The semiconductor device of claim 18, wherein:
the first layer and the second layer of the two or more stacked layers comprise a substrate layer and an active layer, respectively; and
the interfacing region comprises the channel, the channel disposed in the substrate layer.
